(19) United States
(12) Patent Application Publication
(10) Pub. No.: US 2006/0022353 A1
(43) Pub. Date: Feb. 2, 2006

(54) Probe pad arrangement for an integrated circuit and method of forming

(76) Inventors: Sergio A. Ajuria, Austin, TX (US); Kevin J. Hess, Austin, TX (US); Yizhe Huang, Austin, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 10/909,100

(22) Filed: Jul. 30, 2004

(51) Int. Cl. H01L 23/48

(52) U.S. Cl. 257/786

(57) ABSTRACT

An integrated circuit die (10) includes a substrate (64), a plurality of metal interconnect layers (62) formed over the substrate (64), an insulating layer (58), a first pad (12), a second pad (14), and a probe pad (16). The first pad (12) is formed over the insulating layer (58) at an edge (11) of the integrated circuit die (10). The second pad (14) is formed over the insulating layer (58) adjacent to the first pad (12) on a side of the first pad (12) that is opposite to the edge (11). The probe pad (16) is formed over the insulating layer (58) on a side of the second pad (14) that is opposite to the edge (11), wherein the probe pad (16) is electrically connected to the first pad (12). The probe pad (16) may be formed over active circuitry of the substrate instead of over a peripheral area of the die (10), thus reducing the surface area of the die (10).

### FIELD OF THE INVENTION

The present invention relates generally to integrated circuits, and more particularly, arrangements of probe pads of integrated circuits.

### RELATED ART

In the manufacture of integrated circuits the continuing reduction in the size of transistors has had the effect of increasing the number of signal and power supply pads for a given die size. These pads are generally on the perimeter of the die. These pads are limited in how close they can be to each other for one or more reasons. The distance the centers of these pads are apart is called the pad pitch. Due to pad count and pitch limitations, more than one row of pads is needed. Having multiple rows can have the adverse effect of increasing die size due just to the need for the placement of the pads. Even so it is not uncommon for there to be more than one row. One technique that has been used to handle multiple rows is to stagger the pads. This provides better utilization for placing wires during wire bonding but doesn't really change the space required for the pads, especially when taking into account the additional area needed for probing.

Thus, there is a need for improvements with regard to issues related to wire bonding and probing of multiple pad rows as described above.

### BRIEF DESCRIPTION OF THE DRAWINGS

The present invention is illustrated by way of example and not limited by the accompanying figures, in which like references indicate similar elements, and in which:

FIG. 1 is a top view of an integrated circuit according to a first embodiment of the invention; and

FIG. 2 is a cross section of an integrated circuit similar to that of FIG. 1 showing an alternative for a portion of the implementation of that shown in FIG. 1.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION OF THE DRAWINGS

In one aspect an integrated circuit has an outer perimeter of bond pads, an intermediate perimeter of pads that function as both bond pads and probe pads, and an inner perimeter of probe pads that are electrically connected to the bond pads of the outer perimeter. This results in the ability to meet the requirements of probe because the inner perimeter can be spaced further from the intermediate perimeter without causing an increase in die size of the integrated circuit. This is better understood by reference to the drawings and the following description.

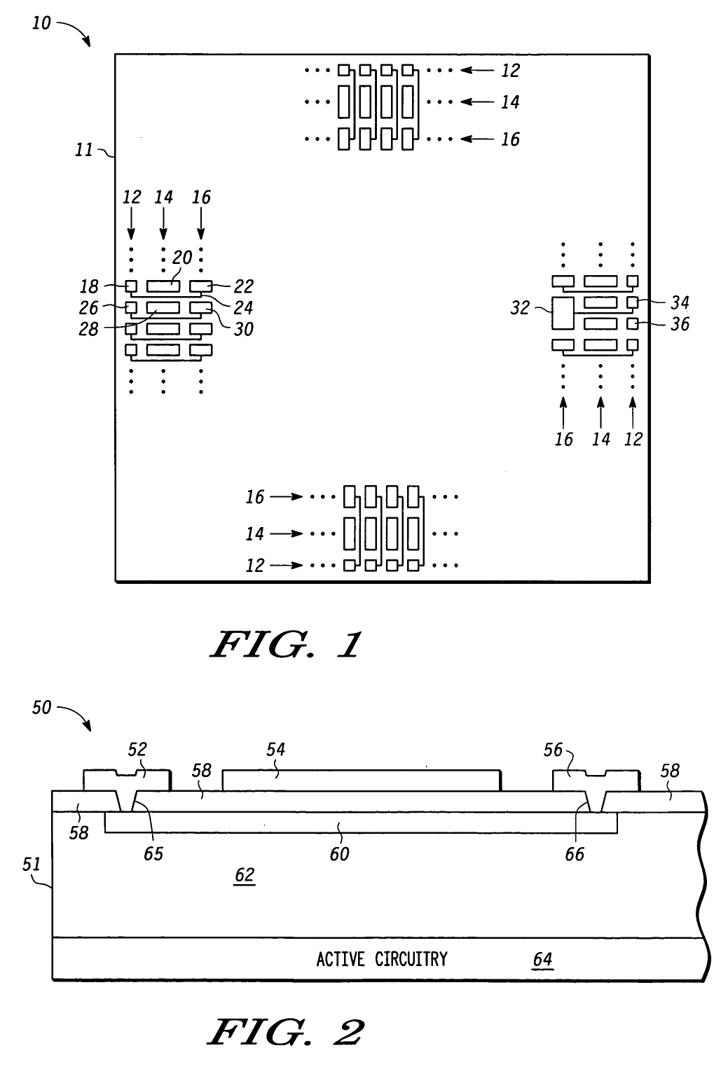

Shown in FIG. 1 is an integrated circuit 10, which is a die, having an edge 11 and comprising an outer perimeter of a plurality of bond pads 12, an intermediate perimeter of a plurality of pads 14 that function as both bond pads and probe pads, and an inner perimeter of plurality of probe pads 16. Integrated circuit 10 also has a passivation layer, an interconnect region under the passivation layer, and a substrate including active circuitry not shown in FIG. 1 but analogous features are shown in FIG. 2. These pluralities of pads 12, 14, and 16 are on a top surface of the integrated circuit over a passivation layer thereof. In this example bond pads 12 are 44 microns on each side at a minimum pitch of 47 microns, and pads 14 are the same width and pitch as bond pads 12 but at a length of 132 microns. Probe pads 16 can vary in width from 44 to 91 microns and can vary in length as well. Bond pads 12 of the outer perimeter are separated from bond pads 14 of the intermediate perimeter by 10 microns. Similarly, pads 14 of the intermediate perimeter are separated from probe pads 16 of the inner perimeter by 10 microns. Bond pads 12 as shown in FIG. 1 are for receiving a wire bond, but could be for another type such as for receiving a bump or ball. Pads 14 on the other hand are big enough so they can receive a probe on one location and be bonded on a different location. Probe pads 16 are big enough to receive a probe. Each of the probe pads 16 is electrically connected to one of the bond pads 12. In FIG. 1 this electrical connection is achieved by metal traces on the surface above the passivation layer running between adjacent pairs of pads 14.

As a specific example, shown in FIG. 1 are bond pads 18 and 26 of bond pads 12, pads 20 and 28 of pads 14, and probe pads 22 and 30 of probe pads 16. Bond pad 18 is adjacent to edge 11. Pad 20 is adjacent to bond pad 18 so that pad 18 is between edge 11 and pad 20. Probe pad 22 is adjacent to pad 20 so that pad 20 is between bond pad 18 and probe pad 22. Similarly, bond pad 26 is adjacent to edge 11 and is also adjacent to bond pad 18. Pad 28 is adjacent to pad 20 and bond pad 26 so that pad 28 is between bond pad 26 and probe pad 30. Probe pad 30 is adjacent to probe pad 22 and to pad 28. A metal trace 24 runs from probe pad 22 to bond pad 18 between pads 20 and 28 to provide the electrical connection between probe pad 22 and bond pad 18. A trace can be quite small so that it can fit safely between pads 20 and 28 that are 13 microns apart.

In FIG. 1 are also shown adjacent bond pads 34 and 36 of bond pads 12 and a probe pad 32 of probe pads 16 that is connected to bond pad 34. In this example, probe pad is 91 microns wide, thus about twice as wide as probe pads 22 and 30, and thus occupies the space that would be occupied by the probe pad that would be connected to bond pad 36. This can be acceptable when the bond pad is a power supply connection such as VDD or ground. To power integrated circuit 10 while probing it, not all power supply connections need to be connected. Thus, in this example, bond pads 12 are all power supply connections so that not all need to be connected to a corresponding probe pad of probe pads 16. Also probe pads 16 are shown as a perimeter of pads in close proximity to the intermediate perimeter of pads 14, but this need not be the case because the electrical connection between bond pads 12 and probe pads 16 is not dependent on being in close proximity. Thus the separation between probe pads 16, which are inside the intermediate perimeter, and pads 14 is variable as needed. This is beneficial because probe requirements are variable in a complex relationship between the rows of probe pads. Thus, relaxing the requirements in one row can avoid the need to do so in another row and the distance between rows is also a variable.

As an alternative to using surface traces between pads to provide electrical connection between corresponding probe pads and bond pads, a conductor can run under the surface. Shown in FIG. 2 is a cross section of an integrated circuit 50 having the same pad layout as for bond pads 12, pads 14, and probe pads 16, but instead of having surface traces for connecting bond pads to probe pads, a conductor runs under the surface to provide such a connection. Integrated circuit 50 has an edge 51 analogous to edge 11 comprises bond pad 52, pad 54, and probe pad 56, which are on the surface of integrated circuit 50. Integrated circuit 50 also comprises a passivation layer 58, whose top surface is the surface of integrated circuit 50, a conductor 60 below passivation layer 58, and interconnect region 62 under conductor 60, and a substrate 64 that includes active circuitry. Integrated circuit 10 of FIG. 1 is similarly constructed with a passivation layer, an interconnect region, and active circuitry. In FIG. 2 conductor 60 is connected to bond pad 52 by a via 65 and to probe pad 56 by a via 66. The approach shown in FIG. 2 for connecting the probe pads to the bond pads avoids requiring space for traces such as trace 24 of FIG. 1, but does add complexity with regard to the connections that pad 54 needs to make with interconnect region 62 and the active circuitry of substrate 64.

It is very common for an integrated circuit to have a region of active circuitry surrounded by a periphery of bond areas. Because the bond areas for a typical integrated circuit require special physical support, functional circuitry, and ESD protection, the bond areas typically establish the outer limit for active circuitry. Thus active circuitry typically cannot extend closer to the perimeter of the integrated circuit, such as edges 11 and 51, than the inner most row of bonding areas; in this case the bonding areas of pads 14. In integrated circuits 10 and 50, the portions of pads 14 used for bonding are these closest to bond pads 12. With probe pads 16 inside pads 14, the only space needed for bonding is at the perimeter of the integrated circuits so that the active circuitry can thus fully utilize the area of integrated circuits 10 and 50. If some of the space needed for probing were nearer the perimeter than the bonding area of pads 14, then it would be difficult to optimize the circuit usage of the area under the probing areas. Because probe areas do not require special support, they have greater flexibility in placement. This is taken advantage of by placing the probe areas that correspond to bond pads 12 in the area inside the perimeter of pads 14. Thus, the probing areas are over active circuitry that can be designed for optimum use of space.

Further, problems arising from the placement of multiple rows of signal and supply pads along the perimeter of an integrated circuit die are alleviated, especially for the case where supply and signal pads are placed along separate rows. The addition of probe pads that are electrically connected to but not contiguous with bond pads offers several benefits. One benefit is the flexibility gained in the physical placement of the probe pads. The probe pad can be located over the active circuitry of the die, allowing the two rows of bond pad areas to be placed in the region closest to the die edge. This shortening the length of wire required to connect the bond pad to the package substrate bond location. In addition, the relocation of the probe area over the active circuitry has the benefit of providing improved access to power and ground supplies for probing and packaging while not increasing the die size.

In the foregoing specification, the invention has been described with reference to specific embodiments. However, one of ordinary skill in the art appreciates that various modifications and changes can be made without departing from the scope of the present invention as set forth in the claims below. For example, other dimensions may be used than those described. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. An integrated circuit die, comprising:
a substrate including active circuitry;
a plurality of metal interconnect layers formed over the substrate;
an insulating layer formed over the plurality of metal interconnect layers;
a plurality of pads formed over the insulating layer along an edge of the integrated circuit die, each of the plurality of pads coupled to a conductor of the plurality of metal interconnect layers;
a plurality of bond pads formed over the insulating layer and positioned between the plurality of pads and the edge, each of the plurality of bond pads coupled to a conductor of the plurality of metal interconnect layers; and
a plurality of probe pads formed over the insulating layer, wherein the plurality of pads are positioned between the plurality of probe pads and the plurality of bond pads, and wherein a probe pad of the plurality of probe pads is electrically connected to a bond pad of the plurality of bond pads.

2. The integrated circuit die of claim 1, wherein the insulating layer is characterized as being a passivation layer.

3. The integrated circuit die of claim 1, wherein the probe pad is electrically connected to the bond pad by an electrical conductor formed over the insulating layer.

4. The integrated circuit die of claim 1, wherein the probe pad is electrically connected to the bond pad by an electrical conductor formed in the metal interconnect layer.

5. The integrated circuit die of claim 4, wherein the electrical conductor comprises copper.

6. The integrated circuit die of claim 4, wherein the electrical conductor comprises aluminum.

7. The integrated circuit die of claim 1, wherein the plurality of bond pads are wire bond pads.

8. The integrated circuit die of claim 1, wherein the plurality of bond pads are for supporting solder bumps.

9. The integrated circuit die of claim 1, wherein each of the plurality of pads comprises a probe region and one of either a wire bond region or a solder bump region, wherein the one of either a wire bond region or a solder bump region of each of the plurality of pads is relatively closer to the plurality of bond pads than the probe region.

10. The integrated circuit die of claim 1, wherein the plurality of bond pads are for being coupled to one of either a power supply voltage or ground.

11. The integrated circuit die of claim 1, wherein the plurality of probe pads are formed over the active circuitry.

12. The integrated circuit die of claim 1, wherein a pad of the plurality of pads comprises at least one of a wire bond region, a solder bump region, or a probe region.

13. The integrated circuit die of claim 1, wherein the plurality of probe pads are positioned adjacent to the plurality of pads.

14. An integrated circuit die, comprising:
a substrate including active circuitry;
a plurality of metal interconnect layers formed over the substrate;
an insulating layer formed over the plurality of metal interconnect layers;
a first pad formed over the insulating layer at an edge of the integrated circuit die;
a second pad formed over the insulating layer adjacent to the first pad on a side of the first pad opposite to the edge; and
a probe pad formed over the insulating layer on a side of the second pad opposite to the edge, wherein the probe pad is electrically connected to the first pad.

15. The integrated circuit die of claim 14, wherein the first pad is a wire bond pad.

16. The integrated circuit die of claim 14, wherein the second pad includes both a wire bond region and a probe region,

17. The integrated circuit die of claim 16, wherein the wire bond region is positioned closer to the first pad than the probe region.

18. The integrated circuit die of claim 14, wherein the first pad is for being coupled to one of a power supply voltage or ground.

19. The integrated circuit die of claim 14, wherein the insulating layer is characterized as being a passivation layer.

20. The integrated circuit die of claim 14, wherein the probe pad is electrically connected to the first pad by an electrical conductor formed over the insulating layer.

21. The integrated circuit die of claim 14, wherein the probe pad is electrically connected to the first pad by an electrical conductor formed in the metal interconnect layer.

22. The integrated circuit die of claim 21, wherein the electrical conductor comprises copper.

23. The integrated circuit die of claim 21, wherein the electrical conductor comprises aluminum.

24. The integrated circuit die of claim 14, wherein the probe pad is formed directly over the active circuitry.

25. A method for forming an integrated circuit, comprising:
providing a substrate including active circuitry;
forming a plurality of metal interconnect layers over the substrate;
forming an insulating layer over the plurality of metal interconnect layers;
forming a first pad over the insulating layer at an edge of the integrated circuit die;
forming a second pad over the insulating layer adjacent to the first pad on a side of the first pad opposite to the edge;
forming a probe pad over the insulating layer on a side of the second pad opposite to the edge; and
electrically connecting the probe pad to the first pad.

26. The method of claim 25, further comprising coupling the first pad to one of either a power supply voltage or ground.

27. The method of claim 25, wherein electrically connecting the probe pad to the first pad further comprises forming an electrical conductor over the insulating layer between the probe pad and the first pad.

28. The method of claim 25, wherein electrically connecting the probe pad to the first pad further comprises forming an electrical conductor in one layer of the plurality of the metal interconnect layers, the electrical conductor connected to both the probe pad and the first pad.

29. The method of claim 25, wherein forming the probe pad comprises forming the probe pad over the active circuitry.
